(19) United States
(12) Patent Application Publication
(10) Pub. No.: US 2013/0082700 A1
(43) Pub. Date: Apr. 4, 2013

(54) NUCLEAR MAGNETIC RESONANCE IMAGING APPARATUS AND NUCLEAR MAGNETIC RESONANCE IMAGING METHOD

(71) Applicants: Natsuhiko Mizutani, Tokyo (JP); Tetsuo Kobayashi, Kyoto-shi (JP); Kiyoshi Ishikawa, Kusatsu-shi (JP)

(72) Inventors: Natsuhiko Mizutani, Tokyo (JP); Tetsuo Kobayashi, Kyoto-shi (JP); Kiyoshi Ishikawa, Kusatsu-shi (JP)

(73) Assignee: CANON KABUSHIKI KAISHA, Tokyo (JP)

(21) Appl. No.: 13/604,225

(22) Filed: Sep. 5, 2012

(30) Foreign Application Priority Data
Sep. 30, 2011 (JP) 2011-216293

(51) Int. Cl. G01R 33/48

(52) U.S. Cl. 324/301

(57) ABSTRACT

The present invention has an object to provide a nuclear magnetic resonance imaging apparatus or the like that avoids a region with zero sensitivity of an optical magnetometer and allows imaging by strong magnetic resonance when a common magnetic field is used as a bias field of an optical magnetometer and as a magnetostatic field to be applied to a sample. When a direction of a magnetostatic field application unit applying a magnetostatic field to a sample is a z direction, alkali metal cell of a scalar magnetometer is arranged so as not to overlap a region to be imaged in a z direction, and so as not to intersect the region to be imaged in an in-plane direction perpendicular to the z direction.

### BACKGROUND OF THE INVENTION

1. Field of the Invention

The present invention relates to a nuclear magnetic resonance imaging apparatus and a nuclear magnetic resonance imaging method.

2. Description of the Related Art

An optical magnetometer with high sensitivity, using electron spin of an alkali metal gas, has been proposed. When the optical magnetometer is used to measure magnetic resonance (perform magnetic imaging), a relationship between a bias field for operating the magnetometer and a magnetostatic field to be applied to a sample is restricted in some extent. This is because a Larmor frequency ω₀ of alkali metal or proton is ω₀=γ_{A}|B| in proportion to magnitude |B| of a magnetic field. A constant of proportion γ_{A} is referred to as a gyromagnetic ratio. A gyromagnetic ratio of nuclear spin of proton is smaller than a gyromagnetic ratio of electron spin of alkali metal, for example, a gyromagnetic ratio of proton is about 1/167 of a gyromagnetic ratio of potassium.

There is a method of matching a Larmor frequency of alkali metal with a Larmor frequency of proton in nuclear magnetic resonance imaging using an optical magnetometer of alkali metal having the above-described property. For example, I. Savukov, S. Seltzer, and M. Romalis, Detection of NMR signals with a radio-frequency atomic magnetometer, Journal of Magnetic Resonance, 185, 214 (2007) discloses a combination of a Helmholtz coil that adjusts a bias field to be applied to alkali metal and a solenoid coil surrounding a sample. With this combination, the bias field and a magnetostatic field to be applied to the sample are independently adjusted, and a Larmor frequency of proton is matched with a Larmor frequency of potassium to obtain a magnetic resonance signal.

Also, there is a known method of causing a bias field of an optical magnetometer and a magnetostatic field to be applied to a sample to have the same uniform magnetic field. As such a method, G. Bevilacqua, V. Biancalana, Y. Dancheva, L. Moi, Journal of Magnetic Resonance, 201, 222 (2009) discloses a method in which, focusing on a vibration component in a direction perpendicular to a bias field of a magnetic dipole in a sample, an active volume of a cell is arranged in a position where a magnetic field generated by the component is parallel to the bias field. In this method, a magnetic field of free induction decay (FID) generated from nuclear magnetic resonance of proton in a magnetostatic field is superimposed on a bias field of potassium, and a Larmor frequency thereof is subjected to frequency modulation. A signal subjected to the frequency modulation is decoded to take out a signal of free induction decay.

In nuclear magnetic resonance imaging using an optical magnetometer, the method of causing a bias field of a magnetometer and a magnetostatic field to be applied to a sample to have the same uniform magnetic field as in G. Bevilacqua, V. Biancalana, Y. Dancheva, L. Moi, Journal of Magnetic Resonance, 201, 222 (2009) can avoid complex adjustment of a magnetic field as in I. Savukov, S. Seltzer, and M. Romalis, Detection of NMR signals with a radio-frequency atomic magnetometer, Journal of Magnetic Resonance, 185, 214 (2007), and a common magnetic field is used as a bias field of an optical magnetometer and as a magnetostatic field to be applied to a sample.

However, conditions has not been clarified required for avoiding a region with zero sensitivity of the optical magnetometer, and for imaging by strong magnetic resonance, when a common magnetic field is as such used as a bias field of an optical magnetometer and as a magnetostatic field to be applied to a sample.

### SUMMARY OF THE INVENTION

The present invention is directed to a nuclear magnetic resonance imaging apparatus and a nuclear magnetic resonance imaging method that avoid a region with zero sensitivity of an optical magnetometer and allows imaging by strong magnetic resonance when a common magnetic field is used as a bias field of an optical magnetometer and as a magnetostatic field to be applied to a sample.

The present invention provides a nuclear magnetic resonance imaging apparatus for performing nuclear magnetic resonance imaging, including: a magnetostatic field application unit that applies a magnetostatic field to a sample placed in a region to be imaged; an RF pulse application unit that applies an RF pulse; a gradient magnetic field application unit that applies a gradient magnetic field; and a nuclear magnetic resonance signal detection unit that detects a nuclear magnetic resonance signal, wherein as the nuclear magnetic resonance signal detection unit, a scalar magnetometer is provided in which sensor that detect the nuclear magnetic resonance signal is constituted by alkali metal cell, a common magnetic field is formed to be usable as a bias field that operates the scalar magnetometer and as a magnetostatic field to be applied to the sample in the magnetostatic field application unit, and when the magnetostatic field application unit applies the magnetostatic field to the sample in a z direction, the alkali metal cell of the scalar magnetometer is arranged so as not to overlap the region to be imaged in the z direction, and so as not to intersect the region to be imaged in an in-plane direction perpendicular to the z direction.

The present invention also provides a nuclear magnetic resonance imaging method for performing nuclear magnetic resonance imaging using: a magnetostatic field application unit that applies a magnetostatic field to a sample placed in a region to be imaged; an RF pulse application unit that applies an RF pulse; a gradient magnetic field application unit that applies a gradient magnetic field; and a nuclear magnetic resonance signal detection unit that detects a nuclear magnetic resonance signal, wherein as the nuclear magnetic resonance signal detection unit, the scalar magnetometer is provided in which sensor that detect the nuclear magnetic resonance signal is constituted by alkali metal cell, and in a case where a bias field that operates the scalar magnetometer is applied as a common magnetic field to the magnetostatic field to be applied to the sample in the magnetostatic field application unit, when the magnetostatic field application unit applies the magnetostatic field to the sample in a z direction, the alkali metal cell of the scalar magnetometer is arranged so as not to overlap the region to be imaged in the z direction, and so as not to intersect the region to be imaged in an in-plane direction perpendicular to the z direction.

According to the present invention, a nuclear magnetic resonance imaging apparatus and a nuclear magnetic resonance imaging method can be realized that avoid a region with zero sensitivity of the optical magnetometer and allow imaging by strong magnetic resonance when a common magnetic field is used as the bias field of the optical magnetometer and as the magnetostatic field to be applied to the sample.

Further features of the present invention will become apparent from the following description of exemplary embodiments with reference to the attached drawings.

### BRIEF DESCRIPTION OF THE DRAWINGS

FIG. 1 illustrates sensitivity distribution of a scalar magnetometer placed at an origin in an embodiment of the present invention.

FIG. 2 illustrates a blind region when the scalar magnetometer is used to measure magnetic resonance in the embodiment of the present invention.

FIG. 3A is a plan view of arrangement of an alkali metal cell in performing nuclear magnetic resonance imaging in the embodiment of the present invention.

FIG. 3B is a side view of FIG. 3A.

FIG. 4 illustrates an exemplary configuration of a nuclear magnetic resonance imaging apparatus in Example 1 of the present invention.

FIG. 5 is a block diagram of an optical magnetometer system in which a module in Example 1 of the present invention is connected to an external light source, a photodetector, and a control system and configured to operate as a scalar-type optical magnetometer.

FIG. 6 illustrates an example of a scalar magnetometer module used in Example 1 of the present invention.

FIGS. 7A, 7B, 7C, 7D, 7E, 7F and 7G illustrate a pulse sequence of a spin echo used in measuring a magnetic resonance signal from the sample to perform imaging in Example 1 of the present invention.

FIG. 8A is a plan view of arrangement of an alkali metal cell for performing nuclear magnetic resonance imaging in Example 2 of the present invention.

FIG. 8B is a side view of FIG. 8A.

FIG. 9A is a plan view of arrangement of an alkali metal cell for performing nuclear magnetic resonance imaging in Example 3 of the present invention.

FIG. 9B is a side view of FIG. 9A.

### DESCRIPTION OF THE EMBODIMENTS

Preferred embodiments of the present invention will now be described in detail in accordance with the accompanying drawings.

The present invention is based on a finding in nuclear magnetic resonance imaging with which when a bias field that operates a scalar magnetometer is applied as a common magnetic field to a magnetostatic field to be applied to a sample in a magnetostatic field application unit, a region with zero sensitivity of an optical magnetometer is avoided to allow imaging by strong magnetic resonance.

To describe the region with zero sensitivity of the optical magnetometer, an exemplary configuration using the scalar magnetometer as the optical magnetometer will be first described in this embodiment. The scalar magnetometer is used as a nuclear magnetic resonance signal detection unit that detects a nuclear magnetic resonance signal in a nuclear magnetic resonance imaging apparatus that performs nuclear magnetic resonance imaging. Specifically, the nuclear magnetic resonance imaging apparatus in this embodiment includes a magnetostatic field application unit that applies a magnetostatic field to a sample placed in a region to be imaged, an RF pulse application unit that applies an RF pulse; a gradient magnetic field application unit that applies a gradient magnetic field; and a nuclear magnetic resonance signal detection unit that detects a nuclear magnetic resonance signal.

In such a nuclear magnetic resonance imaging apparatus, the scalar magnetometer constitutes the nuclear magnetic resonance signal detection unit. The scalar magnetometer is a magnetometer that produces an output depending on magnitude |B| of a magnetic field, which uses a Larmor frequency ω₀ of alkali metal being ω₀=γ_{A}|B| as a principle of measurement.

When magnitude of a magnetostatic field is B_{dc}, magnitude of a FID signal from a sample is B_{ac}, and an angle formed by the magnetostatic field and a magnetic field of the FID signal at a measurement point with an alkali metal cell is θ, the following expression is obtained under a condition that the magnetostatic field B_{dc} is sufficiently larger than the magnetic field B_{ac} of the FID signal.

|B|=(B_{dc}²+B_{ac}²+2 B_{dc} B_{ac} cos θ}^{1/2}≈B_{dc}+B_{ac} cos θ

From this expression, matters described below that are not described in Bevilacqua et al. have been newly found. Specifically, when a sensor is arranged in a position with an increased component in a magnetostatic field direction of the FID signal B_{ac} from the sample, a strong magnetic resonance signal is obtained. The FID signal in the magnetostatic field B_{dc} is constituted by a component B_{ac} that vibrates at an angular frequency ω_{H}=γB_{dc} and a component subjected to transverse relaxation in a relaxation time T₂. Resonance in a shorter time scale than the relaxation time is herein noted.

It can be considered that magnetization m in the magnetostatic field B, includes a component m_{||} parallel to the magnetostatic field and a component m⊥ perpendicular to the magnetostatic field and that vibrates at an angular frequency ω_{H}=γB_{dc}, superimposed on each other. When an angle φ is referred to an angle formed by the magnetization m as a vector and the magnetostatic field, m_{||}=|m| cos φ, and magnitude of m⊥ is |m⊥|=|m|sin φ. In observation of a signal in nuclear magnetic resonance imaging, a magnetic field is observed that is generated by the vector m⊥ and vibrates at the angular frequency ω_{H} with rotation of the vector. A term of sin φ is a proportionality coefficient, which is relaxed in the relaxation time T₂. Thus, for a position where the sensor is arranged, magnetic field distribution is considered of the FID signal generated by the magnetization m⊥ perpendicular to the magnetic field in a sample position. It is found that a large signal can be obtained by the scalar magnetometer by considering an arrangement in which a component of the magnetic field in a magnetostatic field direction is increased. A magnetic field B(d) generated in a position d by the magnetization m⊥ placed at an origin is expressed by the following expression with a unit vector n in a vector d direction.

$$B ( d ) = \frac{{μ}_{0}}{4 π} [ \frac{3 n ( n \cdot {m}_{⊥} ) - {m}_{⊥}}{{\vert d \vert}^{3}} ]$$

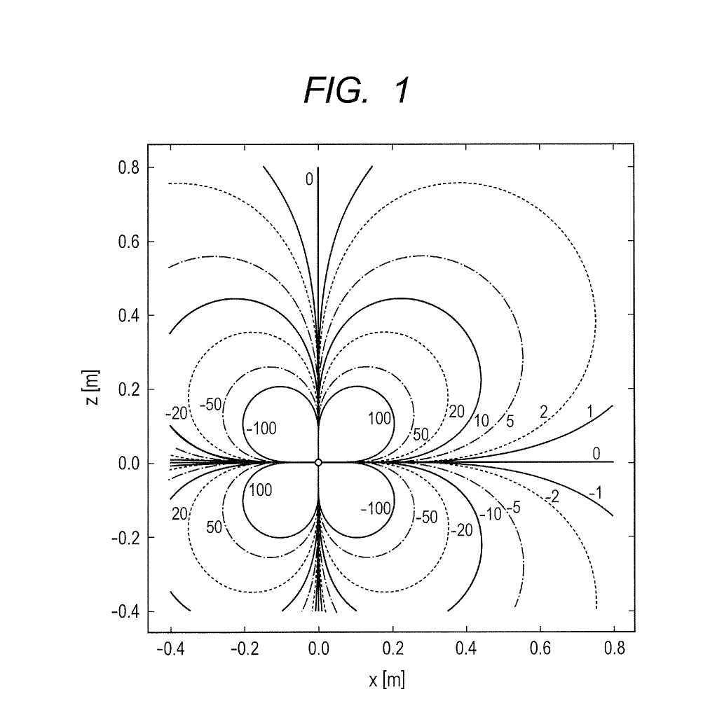

A component B_{||}(d) in the magnetostatic field direction of B(d) is calculated to draw isointensity lines and then obtain a drawing as in FIG. 1. This drawing illustrates calculation results for a z component of a magnetic field generated by magnetization m⊥=(1, 0, 0) with z being placed at an origin in an axial direction as the magnetostatic field direction.

Based on the above calculation, sensitivity distribution of the sensor in performing nuclear magnetic resonance imaging can be considered. For this purpose, distribution of sensor sensitivity may be read and obtained from distribution of magnetic field intensity in FIG. 1. FIG. 1 illustrates (a z component of) a magnetic field generated at a position vector d by the magnetization m⊥ placed at the origin. When we consider a sensor placed at the origin of the coordinates, the interpretation of FIG. 1 can be a sensitivity determined from geometry when the magnetization m⊥ is placed in a position vector −d apart from the sensor. Thus, FIG. 1 may be read to illustrate distribution of sensitivity to signals by the magnetization m⊥ arranged on various points in a space when the scalar magnetometer is placed at the origin. Since the distribution is symmetrical with respect to the origin, there is no need for conversion of vector d into vector −d.

FIG. 1 shows that there is a region with a change in sign in relation to sensitivity of the sensor. The region includes an axis extending in the magnetostatic field direction from the sensor, and a plane including the sensor and perpendicular to the magnetostatic field. A signal from each pixel in nuclear magnetic resonance imaging can be regarded as a spatial average value of a magnetic resonance signal from a voxel. When a voxel in nuclear magnetic resonance imaging crosses the region with a change in sign for response of the sensor, a spatial average in the voxel is an addition of signals with different signs. At this time, a signal obtained from this voxel is significantly small, and substantially close to zero.

In the above description, the sensor has been regarded as an ideal point. Actually, the sensor uses an alkali metal cell having a finite size to read a magnetic field. For the space with decreasing sensor sensitivity, extension of (size of the alkali metal cell+voxel size) needs to be considered.

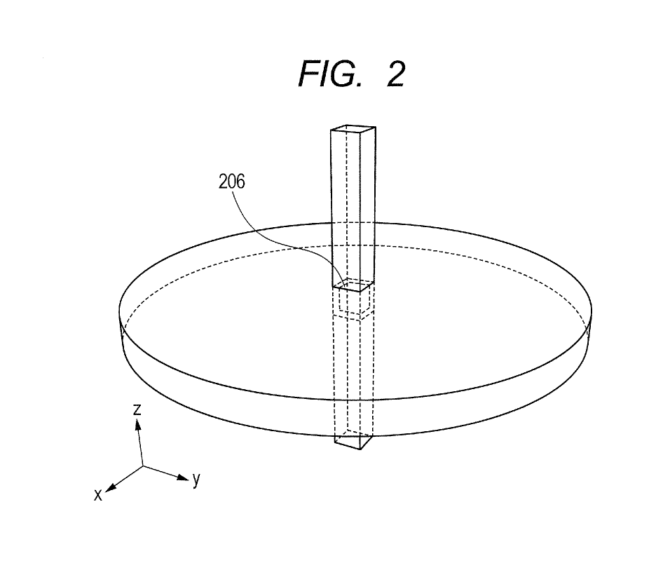

Eventually, around a glass cell 206 into which alkali metal is encapsulated to detect a magnetic field using an optical magnetometer, a region including a width and a depth of a columnar portion and a thickness of a disk portion as shown in FIG. 2 is a region with zero or almost zero sensitivity in nuclear magnetic resonance imaging. Note that the voxel size is a parameter determined in imaging.

The size of the region in FIG. 2 is not previously accurately determined. Typically, when the size of the alkali metal cell is the order of centimeter with respect to the voxel size of the order of millimeter, extension of a blind region is mainly influenced by the size of the alkali metal cell. Specifically, the size (the width and the depth of the columnar portion and the thickness of the disk portion) of the blind region in FIG. 2 may be substantially determined by the size of the alkali metal cell. Thus, it is necessary that after a region to be imaged in nuclear magnetic resonance imaging (MRI) is determined in a sample and position of sensor module of the optical magnetometer is determined so that alkali metal cell is positioned not to overlap the blind region.

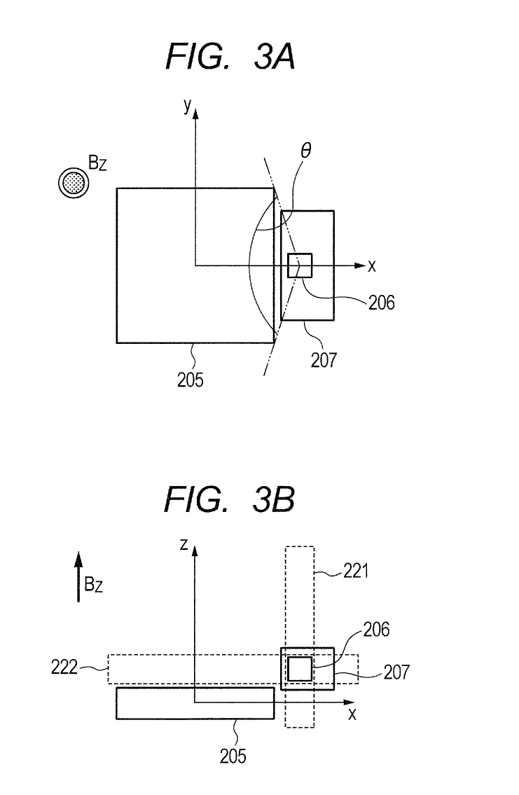

With reference to FIG. 3A and FIG. 3B showing a side view thereof, an exemplary arrangement of sensor in the nuclear magnetic resonance imaging apparatus will be described. As shown in FIG. 3A, the optical magnetometer module 207 is connected to an external controller by an optical fiber. In the module, glass cell 206 into which alkali metal is encapsulated is arranged. A magnetostatic field is applied to a sample in a region 205 to be imaged by MRI in a z direction in the drawing.

At this time, a blind region 221 extends in a magnetostatic field direction of the cell 206. Also, a blind region 222 extends in a direction including the cell 206 and perpendicular to a magnetostatic field.

Specifically, when the region to be imaged 205 is determined, the alkali metal cell 206 of the scalar magnetometer is arranged so that coordinate along the magnetostatic field (z in FIGS. 3A and 3B) do not overlap. The cell 206 is placed so as not to intersect the region to be imaged 205 within a plane (x-y plane in FIG. 3B) perpendicular to the magnetostatic field.

Specifically, when the magnetostatic field application unit applies the magnetostatic field to the sample in the z direction, the alkali metal cell (cell 206) of the scalar magnetometer is arranged so as not to overlap the region to be imaged in the z direction, and so as not to intersect the region to be imaged in an in-plane direction perpendicular to the z direction. Thus, when a common magnetic field is usable as a bias field that operates the scalar magnetometer and a magnetostatic field to be applied to the sample in the magnetostatic field application unit, the region with zero sensitivity of the optical magnetometer is avoided to allow imaging by strong nuclear magnetic resonance.

Further, a larger magnetic signal is obtained in a position closer to the sample. Thus, the cell is arranged in a position close to the region to be imaged as described below.

Specifically, it is desirable to arrange the cell in a position where an angle θ formed by lines connecting each of one end and the other end of the region to be imaged 205 facing the alkali metal cell in the in-plane direction perpendicular to the z direction as a direction of application of the magnetostatic field, and a center of the alkali metal cell (angle θ of the region to be imaged 205 seen from the center of the cell 206) exceeds 90 degrees. If the angle θ of the region to be imaged 205 seen from the center of the cell 206 cannot exceed 90 degrees from the two initial restrictions described above, it is desirable to arrange the cell in a position with an angle θ of at least 60 degrees.

### EXAMPLES

Now, examples of the present invention will be described.

### Example 1

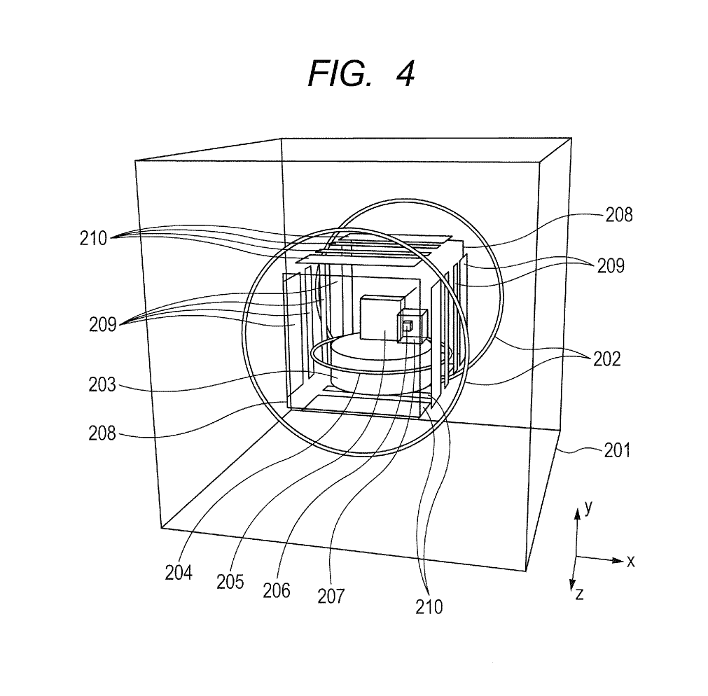

As Example 1, an exemplary configuration of a nuclear magnetic resonance imaging apparatus to which the present invention is applied will be described with reference to FIG. 4. As illustrated in FIG. 4, the nuclear magnetic resonance imaging apparatus in this Example is surrounded by three pairs of coils 201 directed in three axis directions to cancel earth's magnetic field. Further, the nuclear magnetic resonance imaging apparatus includes a pair of Helmholtz coils 202 for applying a magnetostatic field to a sample. The pair of coils 202 apply a magnetostatic field B₀ having intensity of, for example, about 50 μT to 200 μT. A polarization coil 203 generates a magnetic field in a direction perpendicular to the magnetostatic field B₀ to cause spin polarization of the sample. The polarization coil 203 applies a magnetic field of, for example, 40 mT to 100 mT. An RF coil 204 applies a 180° pulse or a 90° pulse to the sample to control a direction of the spin of the sample. The entire nuclear magnetic resonance apparatus is housed in an electromagnetic shield box (not shown) of aluminum to prevent magnetic field noise from measurement environment. FIG. 4 schematically illustrates the region to be imaged 205 in the apparatus. The sample or living body to be placed in the apparatus is sometimes much larger than the region 205.

Closed-loop scalar magnetometer module 207 use alkali metal cell as magnetic sensor for detecting nuclear magnetic resonance. The magnetometer 207 include alkali metal cell 206, and optically read behavior of spin of alkali metal vapor to detect a magnetic field. Details of the scalar magnetometer will be described later. The drawing does not illustrate a light source required to be connected to the module and operated as a scalar magnetometer. This will be described below in detail.

A Gz coil 208, a Gx coil 209, and a Gy coil 210 are provided as coils for applying a gradient magnetic field for imaging. Gz refers to a magnetic field Bz in the z direction having magnetic field intensity (gradient magnetic field) depending on a value of a z coordinate. Similarly, Gy and Gx also refer to the magnetic field Bz in the z direction having magnetic field intensity (gradient magnetic field) depending on values of a y coordinate and an x coordinate.

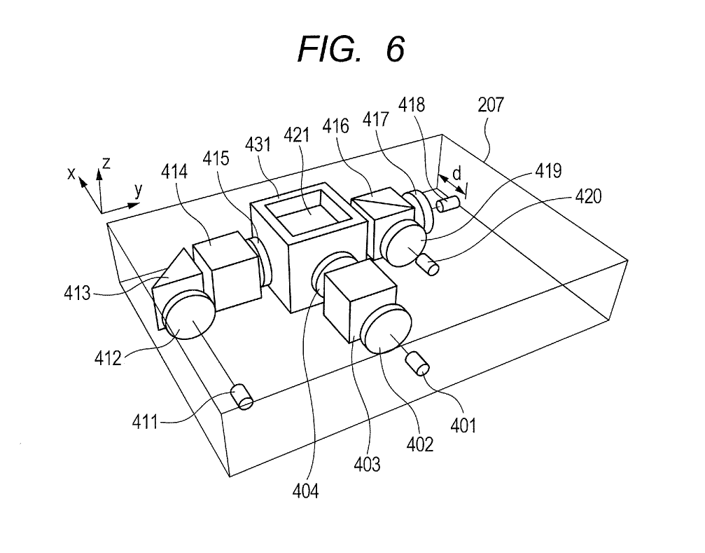

FIG. 6 illustrates an example of the scalar magnetometer module used herein.

A cell 421 is made of a material such as glass, which is transparent to a probe light or a pump light. Potassium (K) as a group of alkali metal atoms is encapsulated into the cell 421 to be airtight. As a buffer gas and a quencher gas, helium (He) and nitrogen (N₂) are encapsulated. The buffer gas prevents diffusion of polarized alkali metal atoms to reduce spin relaxation due to a collision with a cell wall, and thus it is effective for increasing a polarization ratio of alkali metal. An N₂ gas is a quencher gas that takes away energy from K in an excitation state to prevent light emission, and thus it is effective for increasing efficiency of optical pumping.

An oven 431 is provided around the cell 421. To increase density of an alkali metal gas in the cell 421 to operate a magnetometer, the cell 421 is heated to about 200 degrees Celsius maximum. For this purpose, a heater is placed in the oven 431. The oven 431 also serves to prevent heat inside from being released outside, and thus a surface thereof is covered with a heat insulating material. An optical window is placed on an optical path through which the pump light and the probe light described later pass to ensure an optical path. In FIG. 6, an upper side of the oven 431 is open for illustrating the cell 421 inside, but the cell 421 is actually entirely enclosed by the oven.

In an optical system of the pump light, a laser light emitted from an end surface of an optical fiber (not shown) connected to an optical fiber connector 401 extends within a range of a radiation angle determined by numerical aperture (NA) of the optical fiber. The light is converted into a collimated beam by a convex lens 402, and into a circularly polarized pump light by a polarization beam splitter 403 and a quarter-wave plate 404, and then applied to the cell 421.

In an optical system of the probe light, a laser light emitted from an end surface of an optical fiber (not shown) connected to an optical fiber connector 411 extends within a range of a radiation angle determined by numerical aperture (NA) of the optical fiber. The light is converted into a collimated beam by a convex lens 412. In this Example, an optical path is folded back by a mirror 413 to reduce a size of the module. A plane of linear polarization having passed through a polarizer 414 is rotated and adjusted by a half-wave plate 415 to obtain a linearly polarized probe light, which is applied to the cell 421.

In a balance-type light receiving system for polarization measurement, a transmitted light and a reflected light from a polarization beam splitter 416 are focused by condenser lenses 417 and 419. A light focused on an end surface of an optical fiber connected to fiber connectors 418 and 420 is coupled to a waveguide mode of the fiber, and taken out of the module. In the module, the alkali cell is arranged at an end rather than the center of the module so as to be as close as possible to the sample. However, the alkali metal cell has a finite size, and it is placed in the oven including the heater and the heat insulating layer, and thus a distance from an outside of the module to the center of the alkali metal cell is a finite value d. The value d is, for example, about 3 cm.

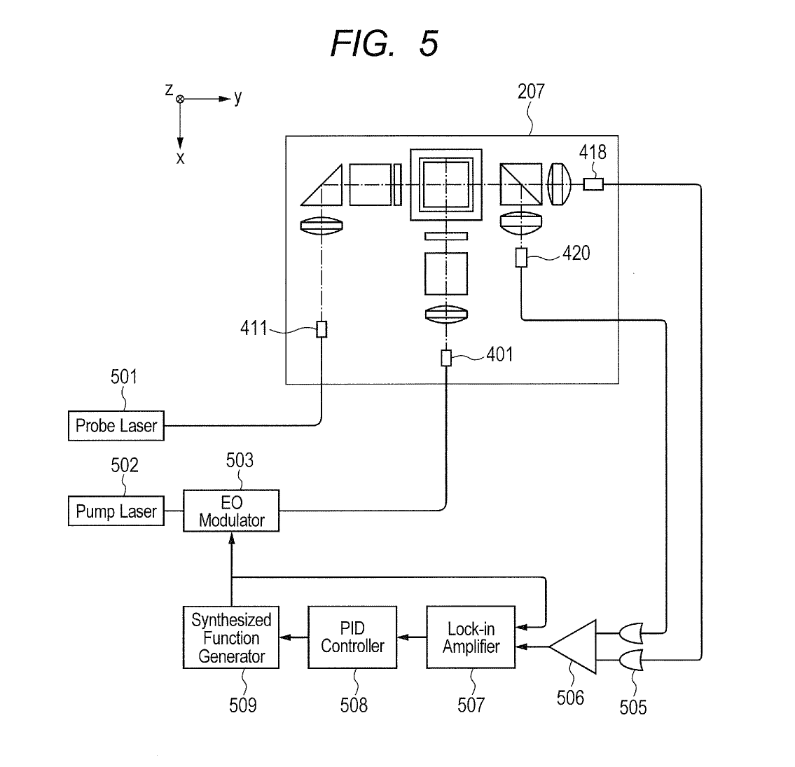

As shown in FIG. 5, the module is connected to an external light source, a photodetector, and a control system, and operated as a scalar optical magnetometer.

In the block diagram in FIG. 5, a wavelength of a pump light emitted from a laser light source 502 for a pump light is matched with a wavelength that allows polarization of a group of atoms in the cell, for example, a D1 resonance line of potassium as alkali metal. The wavelength is about 770 nm. As an optical modulator 503 for intensity modulation of a laser light, an EO modulator is herein used. A light output from the EO modulator is coupled to a polarization-maintaining single mode fiber. An emission end of the optical fiber is connected to an optical fiber connector 401 of the module 207 in FIG. 6.

An output of a laser light emitted from a light source 501 for a probe light is connected to a polarization-maintaining single mode fiber. An emission end of the optical fiber is connected to an optical fiber connector 411 of the module. The probe light is desirably detuned to a certain extent for transition of a resonance line of atoms to avoid unnecessary pumping and to increase a rotation angle of a plane of polarization. For example, a light of 769.9 nm is used.

A multimode fiber is connected to the fiber connectors 418 and 420 of a balance type light receiver of the module, and a set of balance type photodetectors 505 receives a light from the fiber. As an output of an operation amplifier circuit 506 connected to the photodetector, a rotation angle of a plane of polarization can be measured.

The magnetometer is operated under a bias field in a z direction. The pump light is modulated by the EO modulator in this cycle with spin polarization in the cell in an x-axis direction. The spin polarization of alkali metal performs precession at a Larmor frequency around a rotation axis in the z direction as the direction of the bias field. This modulates rotation of a plane of polarization of a probe light passing in a y direction at the Larmor frequency.

A lock-in amplifier 507 performs lock-in detection using an output of a synthesized function generator 509 as a reference signal. Changes in Larmor frequency depending on the magnetic field of the alkali metal cell in the module can be taken out from the lock-in amplifier as a phase shift in response to a reference signal. A PID controller 508 is operated with an amount of phase shift as an error signal, and a feedback signal such that the error signal is 0 is returned to the synthesized function generator 509. Thus, oscillation frequency of the synthesized function generator 509 can be controlled to configure a scalar magnetometer that performs self-oscillation while changing the oscillation frequency depending on intensity of the magnetic field in the cell portion of the module.

The method for configuring the scalar magnetometer is not limited to this, and for example, a magnetometer described below may be used of a type applying an RF magnetic field to force the spin polarization in the alkali metal cell to perform precession around the magnetostatic field.

Specifically, an M-z magnetometer (N. Beverini, E. Alzetta, E. Maccioni, O. Faggioni, C. Carmisciano: A potassium vapor magnetometer optically pumped by a diode laser, on Proceeding of the 12th European Forum on Time and Frequency (EFTF 98)) may be used.

Also, an M-x magnetometer (S. Groeger, G. Bison, J. -L. Schenker, R. Wynands and A. Weis, A high-sensitivity laser-pumped Mx magnetometer, The European Physical Journal D - Atomic, Molecular, Optical and Plasma Physics, Volume 38, 239-247) may be used.

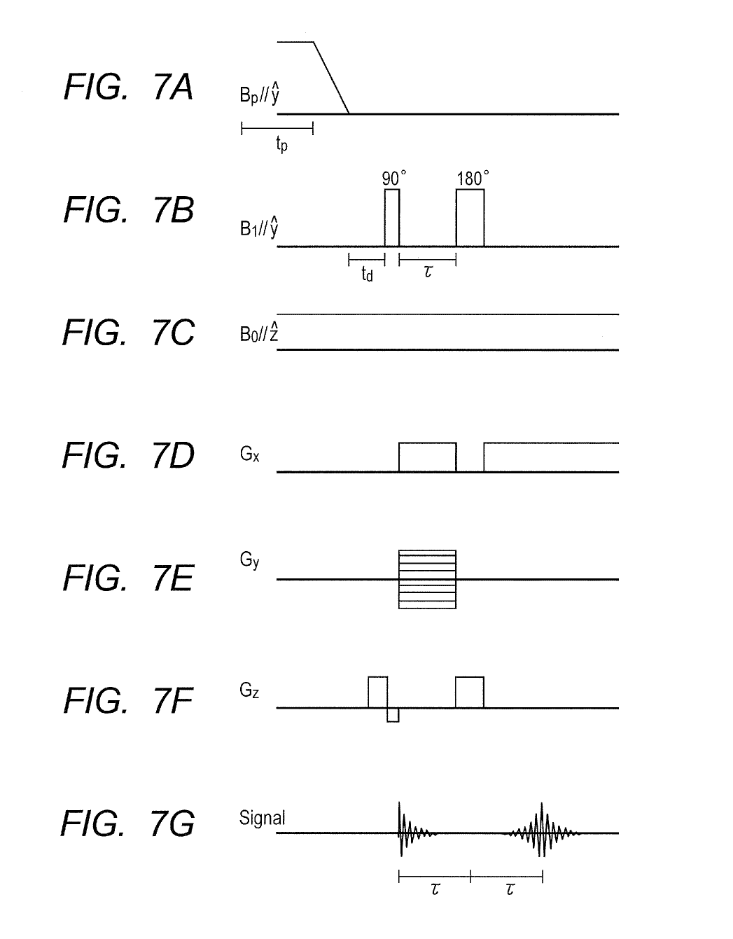

With this apparatus, a pulse sequence of a spin echo as shown in FIGS. 7A, 7B, 7C, 7D, 7E, 7F and 7G is used to measure a magnetic resonance signal from a sample to perform imaging. A constant current is passed through the pair of Helmholtz coils 202 from start to finish of measurement, a magnetostatic field B₀ in a z direction (in the drawings, this is shown by a character z with a circumflex) is generated and applied to the sample and the scalar magnetometer 207 (FIG. 7C).

First, a current is passed through a polarization coil 203, a magnetic field in a y direction (in the drawings, this is shown by a character y with a circumflex) having magnitude of 80 mT is generated to polarize a sample (FIG. 7A). An application time tₚ of the magnetic field is desirably longer than a longitudinal relaxation time of proton spin of the sample. A current to be passed through the polarization coil 203 is quickly reduced to align the spin of the sample in the z direction. When a delay time t_{d} has passed, a 90° pulse is applied from the RF coil 204 while a slice selection gradient magnetic field generated by the Gz coil 208 is being applied, thereby generating an FID signal (FIGS. 7B and 7F). A re-converging gradient magnetic field pulse is applied to align the phase of the spin. A gradient magnetic field is generated by the Gy coil 209 for a y axis in the phase encoding direction and added to the sample (FIG. 7E). Simultaneously, a gradient magnetic field is applied to the Gx coil 210 for an x axis for frequency encoding (FIG. 7D). After a time τ has passed, a 180° pulse is applied to invert by 180° a rotation phase of the spin of the sample (FIG. 7B), and a gradient magnetic field is again applied to the Gx coil for the x axis for frequency encoding (FIG. 7D). After a time 2τ has passed from the first 90° pulse, a peak of the spin echo is observed (FIG. 7G). A phase encoding step is repeated for the number of divided parts in the y-axis direction to generate different Gy, obtain all data, and generate an image of an actual space.

The pulse sequence for imaging from the magnetic resonance signal is not limited to this. For example, known gradient echoing may be applied. Instead of slice selection, imaging of a 3D region with the z-axis direction being a phase encoding direction may be applied.

### Example 2

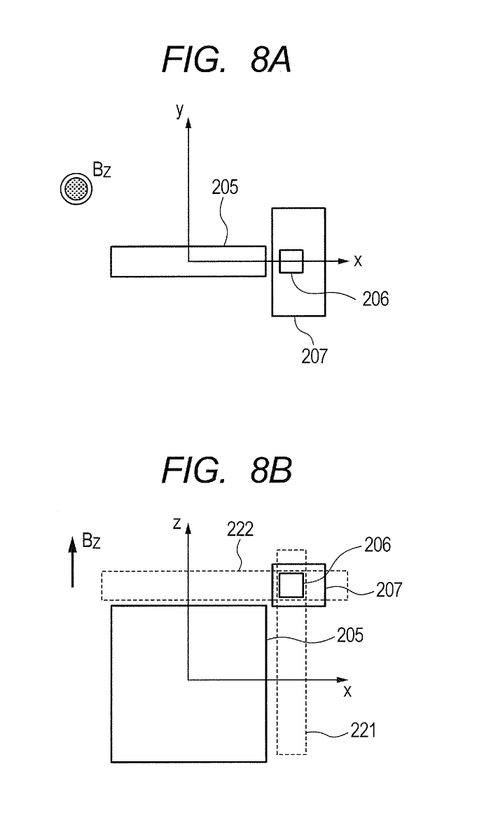

As Example 2, an exemplary configuration with a shape of a region to be imaged different from that in Example 1 will be described with reference to FIG. 8A and FIG. 8B showing a side view thereof.

In Example 1, for a region to be imaged, a sectional shape of a region in the z direction is a thin plate-like shape, and a sectional shape in an in-plane direction perpendicular to the z direction is a square shape with a size larger than a thickness of the thin plate on a side.

On the other hand, in this Example, for a region to be imaged, a sectional shape in the in-plane direction perpendicular to the z direction is a thin plate-like shape, and a sectional shape of a region in the z direction is a square shape with a size larger than a thickness of the thin plate on a side. Specifically, as shown in FIG. 8A, the region is a thin plate-like region in the y direction.

Also in this case, there is the same restriction as described in the embodiment. Specifically, when a region to be imaged 205 is determined, an alkali metal cell 206 of scalar magnetometer is arranged so that coordinate (z in FIG. 8B) along a magnetostatic field do not overlap the region to be imaged 205. The cell 206 is to be arranged so as not to intersect the region to be imaged 205 within a plane (x-y plane in FIG. 8B) perpendicular to the magnetostatic field.

Further, a larger magnetic signal is obtained in a position closer to the sample. Thus, the cell 206 is desirably arranged in a position close to the sample as described below. Specifically, it is desirable to arrange the cell in a position where an angle θ formed by lines connecting each of one end and the other end of the region to be imaged facing the alkali metal cell of the scalar magnetometer in the in-plane direction perpendicular to the z direction as a direction of application of the magnetostatic field, and a center of the alkali metal cell of the scalar magnetometer (angle θ of the region to be imaged 205 seen from the center of the cell 206) is desirably at least 60 degrees when the angle cannot exceed degrees from the two initial restrictions described above. Note that since the angle θ of the region to be imaged 205 seen from the center of the cell 206 is defined by the thickness of the region to be imaged 205, in some cases the amount of the angle becomes smaller than the above.

### Example 3

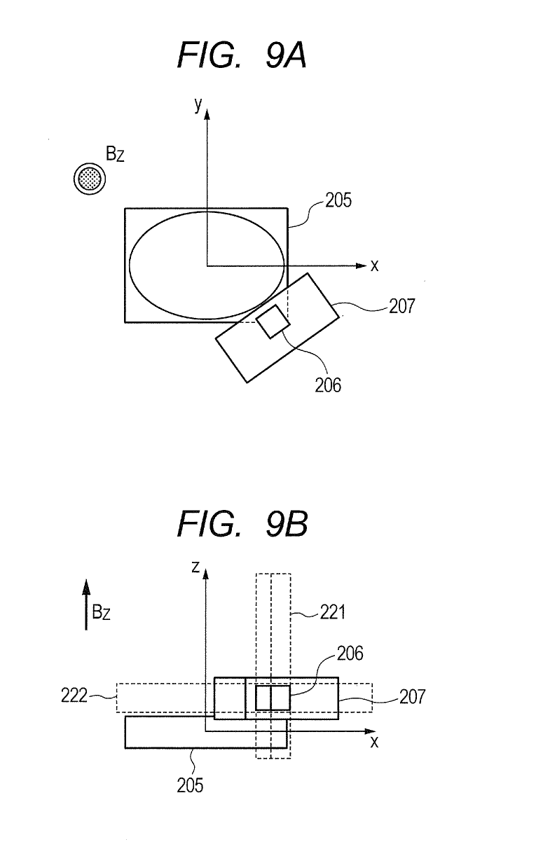

In Example 3, an exemplary possible arrangement of sensors when it is found that a sample in a space to be imaged does not completely fill the space to be imaged and there is a region only with air in an image will be described with reference to FIG. 9A and FIG. 9B showing a side view thereof.

For example, when the region to be imaged includes an elliptic cylindrical sample region in the region to be imaged, specifically, when a space to be imaged 205 includes an elliptic cylindrical sample, the sensors are arranged as in FIG. 9A. Specifically, the sensor module 207 is arranged along a side surface of the elliptic cylinder, and thus if the cell enter the space to be imaged, the cell does not become an obstacle in practice. As shown in FIG. 9A, the cell 206 is arranged so as not to intersect the sample within a plane (x-y plane in FIG. 9B) perpendicular to the magnetostatic field, thereby allowing configuration of an image. The alkali metal cell 206 is arranged so that coordinates along the magnetostatic field do not overlap. These matters are the same as in Examples 1 and 2.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-216293, filed Sep. 30, 2011, which is hereby incorporated by reference herein in its entirety.

What is claimed is:

1. A nuclear magnetic resonance imaging apparatus for performing nuclear magnetic resonance imaging, comprising:
a magnetostatic field application unit configured to apply a magnetostatic field to a sample placed in a region to be imaged;
an RF pulse application unit configured to apply an RF pulse;
a gradient magnetic field application unit configured to apply a gradient magnetic field; and
a nuclear magnetic resonance signal detection unit configured to detect a nuclear magnetic resonance signal,
wherein as the nuclear magnetic resonance signal detection unit, a scalar magnetometer is provided in which a sensor that detect the nuclear magnetic resonance signal is constituted by alkali metal cell,
a common magnetic field is usable as a bias field that operates the scalar magnetometer and as a magnetostatic field to be applied to the sample in the magnetostatic field application unit, and
when the magnetostatic field application unit applies the magnetostatic field to the sample in a z direction, the alkali metal cell of the scalar magnetometer is arranged so as not to overlap the region to be imaged in the z direction, and not to intersect the region to be imaged in an in-plane direction perpendicular to the z direction.

2. The nuclear magnetic resonance imaging apparatus according to claim 1, wherein the alkali metal cell of the scalar magnetometer is arranged in a position where, an angle formed by, lines connecting each of one end and the other end of the region to be imaged facing the alkali metal cell of the scalar magnetometer in the in-plane direction perpendicular to the z direction, and a center of the alkali metal cell of the scalar magnetometer, exceeds 90 degrees.

3. The nuclear magnetic resonance imaging apparatus according to claim 1, wherein the alkali metal cell of the scalar magnetometer is arranged in a position where, an angle formed by, lines connecting each of one end and the other end of the region to be imaged facing the alkali metal cell of the scalar magnetometer in the in-plane direction perpendicular to the z direction, and a center of the alkali metal cell of the scalar magnetometer, exceeds 60 degrees.

4. The nuclear magnetic resonance imaging apparatus according to claim 1, wherein for the region to be imaged, a sectional shape of a region in the z direction is a thin plate-like shape, and a sectional shape in the in-plane direction perpendicular to the z direction is a square shape with a size larger than a thickness of the thin plate on a side.

5. The nuclear magnetic resonance imaging apparatus according to claim 1, wherein for the region to be imaged, a sectional shape in the in-plane direction perpendicular to the z direction is a thin plate-like shape, and a sectional shape of a region in the z direction is a square shape with a size larger than a thickness of the thin plate on a side.

6. The nuclear magnetic resonance imaging apparatus according to claim 1, wherein when the region to be imaged includes an elliptic cylindrical sample region in the region to be imaged, the alkali metal cell of the scalar magnetometer is arranged so as not to overlap the elliptic cylindrical sample region in the region to be imaged in the z direction, and arranged along a side surface of the elliptic cylindrical sample region in the in-plane direction perpendicular to the z direction so as not to intersect the elliptic cylindrical sample region.

7. A nuclear magnetic resonance imaging method for performing nuclear magnetic resonance imaging using:
a magnetostatic field application unit configured to apply a magnetostatic field to a sample placed in a region to be imaged;
an RF pulse application unit configured to apply an RF pulse;
a gradient magnetic field application unit configured to apply a gradient magnetic field; and
a nuclear magnetic resonance signal detection unit configured to detect a nuclear magnetic resonance signal,
wherein as the nuclear magnetic resonance signal detection unit, a scalar magnetometer is provided in which a sensor that detect the nuclear magnetic resonance signal are constituted by alkali metal cell, and
in a case where a bias field that operates the scalar magnetometer is applied as a common magnetic field to a magnetostatic field to be applied to the sample in the magnetostatic field application unit, when the magnetostatic field application unit applies the magnetostatic field to the sample in a z direction, the alkali metal cell of the scalar magnetometer is arranged so as not to overlap the region to be imaged in the z direction, and so as not to intersect the region to be imaged in an in-plane direction perpendicular to the z direction.

8. The nuclear magnetic resonance imaging method according to claim 7, wherein the alkali metal cell of the scalar magnetometer is arranged in a position where, an angle formed by, lines connecting each of one end and the other end of the region to be imaged facing the alkali metal cell of the scalar magnetometer in the in-plane direction perpendicular to the z direction, and a center of the alkali metal cell of the scalar magnetometer, exceeds 90 degrees.

9. The nuclear magnetic resonance imaging method according to claim 7, wherein the alkali metal cell of the scalar magnetometer is arranged in a position where, an angle formed by, lines connecting each of one end and the other end of the region to be imaged facing the alkali metal cell of the scalar magnetometer in the in-plane direction perpendicular to the z direction, and a center of the alkali metal cell of the scalar magnetometer, exceeds 60 degrees.

10. The nuclear magnetic resonance imaging method according to claim 7, wherein for the region to be imaged, a sectional shape of a region in the z direction is a thin plate-like shape, and a sectional shape in the in-plane direction perpendicular to the z direction is a square shape with a size larger than a thickness of the thin plate on a side.

11. The nuclear magnetic resonance imaging method according to claim 7, wherein for the region to be imaged, a sectional shape in the in-plane direction perpendicular to the z direction is a thin plate-like shape, and a sectional shape of a region in the z direction is a square shape with a size larger than a thickness of the thin plate on a side.

12. The nuclear magnetic resonance imaging method according to claim 7, wherein when the region to be imaged includes an elliptic cylindrical sample region in the region to be imaged, the alkali metal cell of the scalar magnetometer is arranged so as not to overlap the elliptic cylindrical sample region in the region to be imaged in the z direction, and arranged along a side surface of the elliptic cylindrical sample region in the in-plane direction perpendicular to the z direction so as not to intersect the elliptic cylindrical sample region.
